(19) United States
(12) Patent Application Publication
(10) Pub. No.: US 2015/0301111 A1
(43) Pub. Date: Oct. 22, 2015

(54) MODULE FOR A FUSED SWITCH ARRANGEMENT WITH A MEASURING DEVICE, AND ALSO A FUSE HOLDER FOR A MODULE OR A FUSED SWITCH ARRANGEMENT

(71) Applicant: Klaus Bruchmann, Coburg (DE)

(72) Inventor: Klaus Bruchmann, Coburg (DE)

(73) Assignee: Klaus Bruchmann GmbH, Weisskirchen an der Traun (AT)

(21) Appl. No.: 14/422,038

(22) PCT Filed: Aug. 17, 2012
(86) PCT No.: PCT/EP2012/003516

§ 371 Date: May 19, 2015

(51) Int. Cl. G01R 31/327; H05K 5/00; H02J 5/00

(52) U.S. Cl. CPC G01R 31/327; H02J 5/005; H05K 5/0017

(57) ABSTRACT

A fused switch arrangement for busbar systems or built-in devices is provided, in particular with one or a plurality of fused switch units for purposes of accommodating in each case a fuse holder, which is designed such that it can accommodate a fuse insert, and with a measuring device for purposes of determining electrical operating values of the fused switch arrangement, wherein the measuring device has a set of measurement electronics and at least one display device for purposes of displaying at least one of the electrical operating values determined by the measuring device, and wherein the module comprises at least one coil device, which is designed such that by means of induction it can provide energy for the set of measurement electronics and/or the at least one display device. The present invention furthermore concerns a fuse holder for a module, in particular for a fused switch arrangement.

The present invention relates to a module for a fused switch arrangement, in particular for a fused switch arrangement for busbar systems or for built-in devices. 3-pole fused switch arrangements or built-in devices with three fused switch units are preferably used; however, it is also possible to provide 2-pole or multi-pole fused switch arrangements or built-in devices. In exceptional cases even a 1-pole fused switch arrangement or a 1-pole built-in device is possible. Such devices are in particular deployed for the protection of alternating current circuits, wherein 3-pole units are as a rule necessary in such applications.

A multi-pole fused switch arrangement for busbars is, for example, of known art from DE 199 37 017 C1.

It is an object of the present invention to provide a module for a fused switch arrangement, in particular for a multi-pole fused switch arrangement or for a built-in device, as well as fuse holders for a module or for fused switch arrangements or built-in devices, which enable a better and/or more convenient utilisation or operation by the user. This object is achieved by means of a module in accordance with claim 1 and a fuse holder in accordance with claim 14. Claims 2 to 13 concern particularly advantageous forms of embodiment of the inventive module; Claims 15 to 17 concern particularly advantageous forms of embodiment of the inventive fuse holder.

In accordance with the invention the module comprises a measuring device for purposes of measuring electrical operating values, wherein the measuring device has a set of measurement electronics and at least one display device for purposes of displaying at least one of the electrical operating values measured by the measuring device. Furthermore the inventive module comprises at least one coil device, which is designed such that by means of induction it can provide energy for the measuring device, in particular for the set of measurement electronics and/or the display device, in particular it can provide at least temporarily the total energy supply for the set of measurement electronics and/or the display device.

In the context of this invention the term “electrical operating values” is to be understood to mean electrical values that pertain to the operation of the module or a fused switch arrangement, or sub-units of the fused switch arrangement, in particular individual fused switch units. In particular such electrical operating values comprise current values, voltage values and/or power values. Electrical operating values can pertain to values that pertain to the module or a fused switch arrangement as a whole; however the electrical operating values preferably pertain to values of individual units or phases of the system, and/or, in particular, individual fuse inserts.

In accordance with the invention the at least one coil device is designed such that by means of induction it can provide energy for the measuring device, in particular for the set of measurement electronics and/or the display device, in particular if the module or a fused switch arrangement is in operation, in particular if it is, for example, connected to a busbar system, if it takes the form of a fused switch arrangement for a busbar system, or is connected to another power line, for example by means of wiring.

The current, which flows through individual elements of the module or a fused switch arrangement, in particular through individual fuse inserts, induces by means of the coil device a current that can be made available directly or indirectly to the measuring device, so that the measuring device and/or the display device, at least partially or at least temporarily, does not require any additional energy supply, or requires a smaller supply of energy.

The inventive module has the advantage that electrical operating values of the module, or individual phases of the module or a fused switch arrangement are directly visible to the user, such that the user can immediately discern the operating state. In this manner useful information is on the one hand made available to the user, while on the other hand in particular possible operating errors are avoided.

A further important advantage of the inventive module is that it comprises at least one coil device, which is designed such that by means of induction it can provide energy for the measuring device, and/or the display device, such that it is also possible to operate the measuring device and the display device, at least temporarily, without an additional energy supply, be this an electrical terminal connection, or a battery, or an accumulator.

In the context of this invention a module takes the particular form of a sub-module or individual components of a fused switch arrangement, in particular of a fused switch arrangement for busbar systems, or of components or a sub-module of a built-in device. A preferred form of embodiment of a module can be implemented in terms of the total fused switch arrangement, in particular the fused switch arrangement for busbar systems, or in terms of the built-in device itself In accordance with another preferred form of embodiment the module takes the form of a busbar adapter, which can be positioned on a busbar system, and to which in turn built-in devices, in particular rail-mounted devices, can be attached.

The coil device preferably comprises a coil former and at least one coil winding, wherein in a particularly preferred form of embodiment the coil device comprises at least two coil windings. At least a first coil winding can be designed such that it provides the energy supply for the measuring device and/or the display device, wherein preferably at least a second coil device can be directly or indirectly connected with the measuring device such that by means of the at least one second coil winding and the measuring device electrical operating values of the fused switch arrangement can be determined. The coil device can therefore on the one hand be designed such that it just provides the energy supply for the measuring device and/or the display device; however it can also be preferably designed such that in addition it serves to provide the measurements of the electrical operating values, such that a dual use is enabled in a simple and effective manner.

In a preferred form of embodiment the coil device is externally an insulating body, wherein it is further preferred for the coil winding outputs to be galvanically separated from the main current path. This has the advantage that the coil device is securely separated from the actual current circuit.

The measuring device is preferably designed such that the electrical operating values for individual phases, in particular of a fused switch arrangement, can be separately determined. This has the advantage that the electrical operating values can be displayed in more detail, namely for each phase, which provides the user with better and more reliable information concerning the total system.

In a particular form of embodiment of the module provision is preferably made for the measuring device for each phase to comprise its own set of measurement electronics and/or for each phase at least one coil device.

In one form of embodiment of the inventive module the at least one set of measurement electronics and/or the at least one display device and/or at least one coil device can be provided in or on the housing of the module, for example, the housing of a fused switch arrangement. This has the advantage that these elements are always connected with the module or a fused switch arrangement; also as a result there exists the possibility of attaching all elements in as space-saving a manner as possible, and in a cost-effective manner for manufacture, and/or of arranging the display device such that it is particularly easily visible to the user. Also such a form of embodiment has the advantage that a single display device can be provided for all phases.

In the case of another module the latter comprises a fuse holder for each phase and each fuse insert, wherein preferably at least one fuse holder, particularly preferably each fuse holder, comprises a set of measurement electronics, at least one display device and at least one coil device. Such a device has the advantage that for each individual phase and for each individual fuse insert an independent measurement takes place and the values for each phase can be separately displayed; furthermore the values can be displayed directly in the vicinity of the related fuse insert, namely on the fuse holder. Furthermore this configuration has the advantage that in the case in which a set of measurement electronics for a display device or a coil device is damaged or no longer functions, it is just necessary to replace a fuse holder.

In a further form of embodiment at least one display device is designed such that it can be detached from the module and/or from a fuse holder. Such a detachable display device can, for example, be connected with the module, in particular with a housing of the module, or with a fuse holder, by means of a plug-in device. In another preferred form of embodiment a wireless connection is provided. In particular the wireless connection has the advantage that the display device can be arranged remotely from the module, for example, from a fused switch arrangement, and therefore can be arranged in a particularly preferred position for the user.

In a further form of embodiment the module also comprises an accumulator and/or a battery and/or a solar cell, wherein these additional energy supplies are designed such that they can supply energy to the measuring device. This can be of advantage in order to supply further energy to the measuring device in addition to the energy generated by induction by means of the coil device, with which, for example, the electrical operating values can be determined more accurately, or else electrical operating values can be determined, even if the current, i.e. the energy, which flows through the module or a fused switch unit, or through a phase, is relatively low. A further advantage of such an additional energy supply unit is that the measuring device and/or the display device then also function if the module or a fused switch arrangement for the busbar system are not in operation, i.e. no current is flowing through the module or parts of the module.

In a further preferred form of embodiment the module also comprises a neutral conductor, which is connected onto the measuring device. With this the electrical operating results can be determined more accurately and/or additional electrical operating values, such as, for example, the power, can be determined This has the advantage that further conclusions can be drawn concerning the system in operation.

The invention furthermore concerns a fuse holder for a module, for example, a fused switch arrangement, which is designed such that it can accommodate a fuse insert. In accordance with the invention the fuse holder comprises a measuring device for purposes of measuring electrical operating values, wherein the measuring device has a set of measurement electronics and at least one display device for purposes of displaying at least one of the electrical operating values determined by the measuring device. The inventive fuse holder comprises at least one coil device, which is designed such that by means of induction it can provide an energy supply for the set of measurement electronics and/or the display device.

Such a fuse holder has the advantage that it can be inserted into any module, also into modules or fused switch arrangements in accordance with the prior art, wherein the above-described advantages are achieved.

In a particularly preferred form of embodiment a module or a fuse holder in accordance with the present invention also comprises a button, with which the measuring device can be switched on or off, e.g., can be activated for a short period of time. This has the advantage that the measuring device is then activated only if it is actually being used, or it is useful for the user.

As an additional, optional possibility for such a button in one form of embodiment provision can also be made for a switchover of the measuring device, or the function of the measuring device, to be possible by means of the button. For example, by means of a button the measuring device can be switched over from a measurement of the current to a measurement of the power. A further option is to allow a minimum value, a maximum value, or an average value of the electrical operating values to be displayed by means of the button, for example, over a particular period of time to be determined.

With regard to a particularly advantageous configuration of such a fuse holder, or a measuring device, or a coil device, which is provided in an inventive module, reference is made to the above embodiments for purposes of avoiding repetition.

These and further features of the present invention are further clarified with the aid of the following figures, which show particularly advantageous forms of embodiment more clearly:

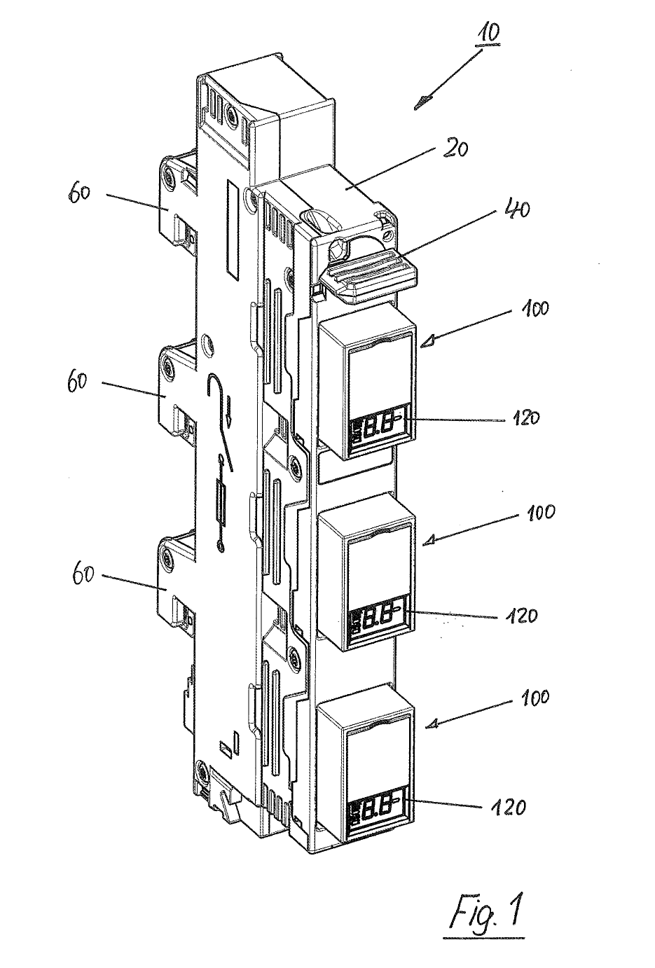

FIG. 1 shows a form of embodiment of an inventive module;

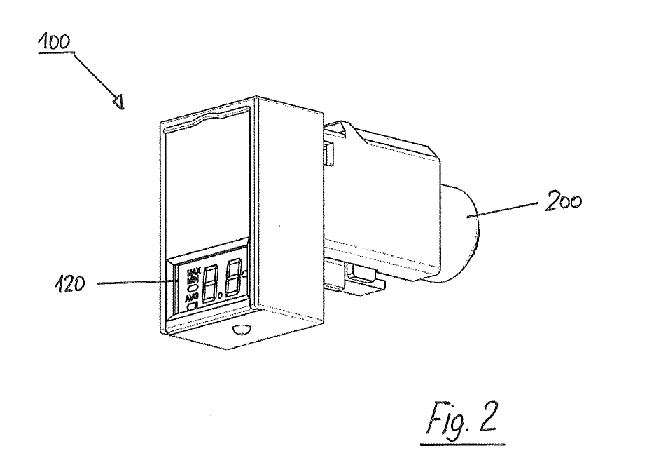

FIG. 2 shows a form of embodiment of an inventive fuse holder;

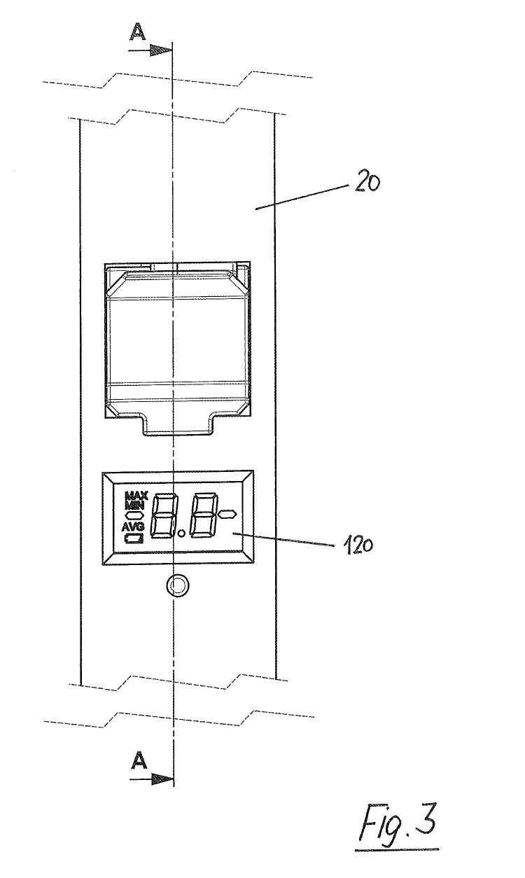

FIG. 3 shows a scrap view of a housing of a form of embodiment of an inventive module;

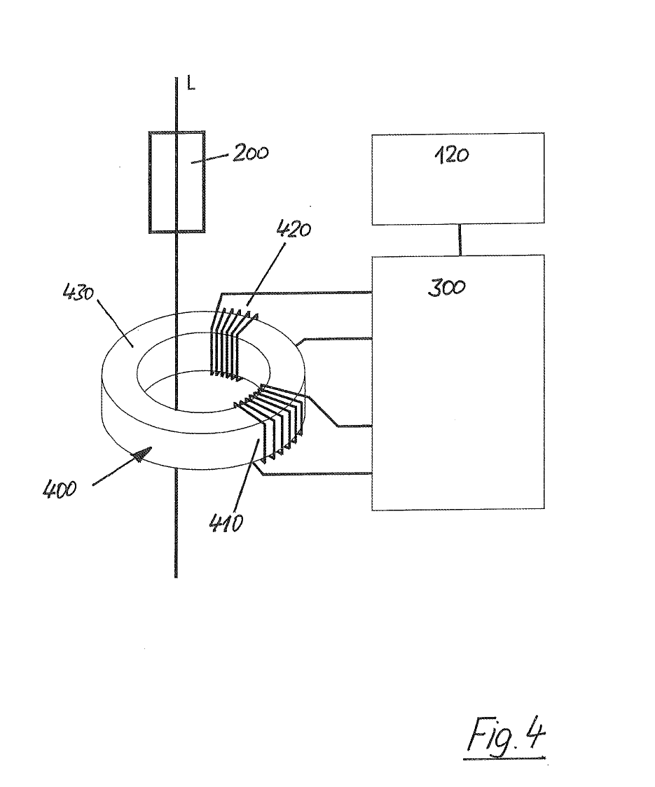

FIG. 4 shows a schematic diagram of some elements of an inventive module or an inventive fuse holder;

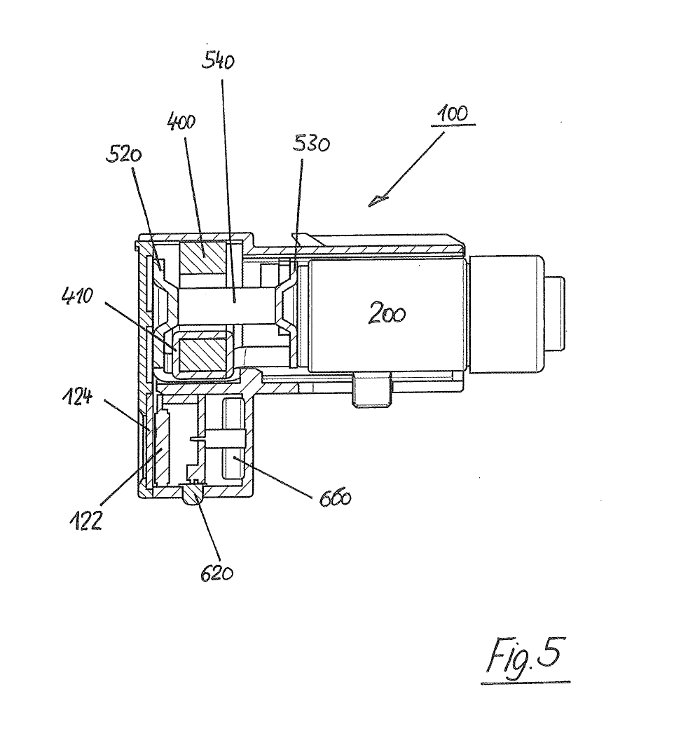

FIG. 5 shows in cross-section a form of embodiment of an inventive fuse holder;

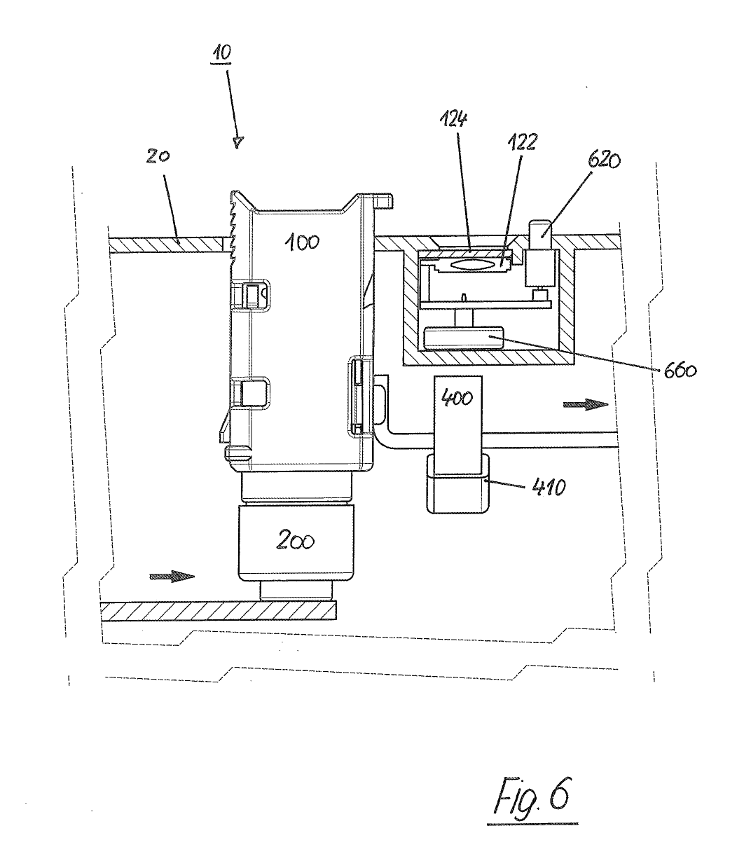

FIG. 6 shows a scrap cross-sectional view of a form of embodiment of an inventive module;

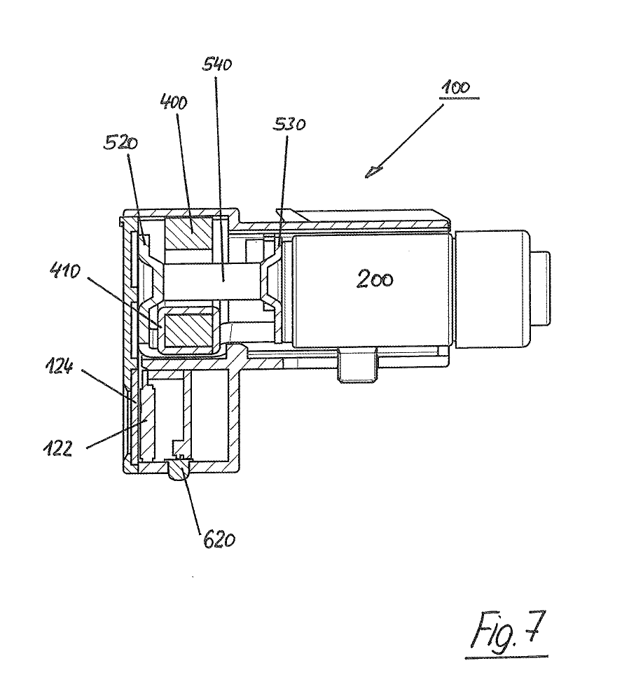

FIG. 7 shows a cross-sectional view of a further form of embodiment of an inventive fuse holder;

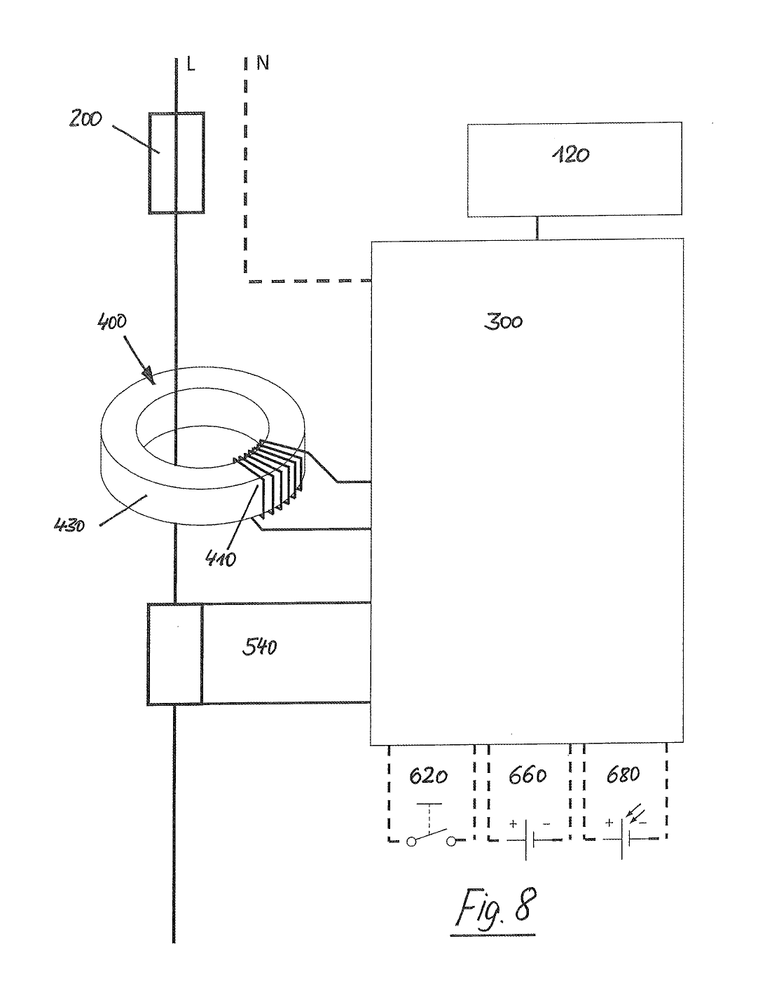

FIG. 8 shows a schematic diagram of some elements of an inventive module or an inventive fuse holder in a further form of embodiment;

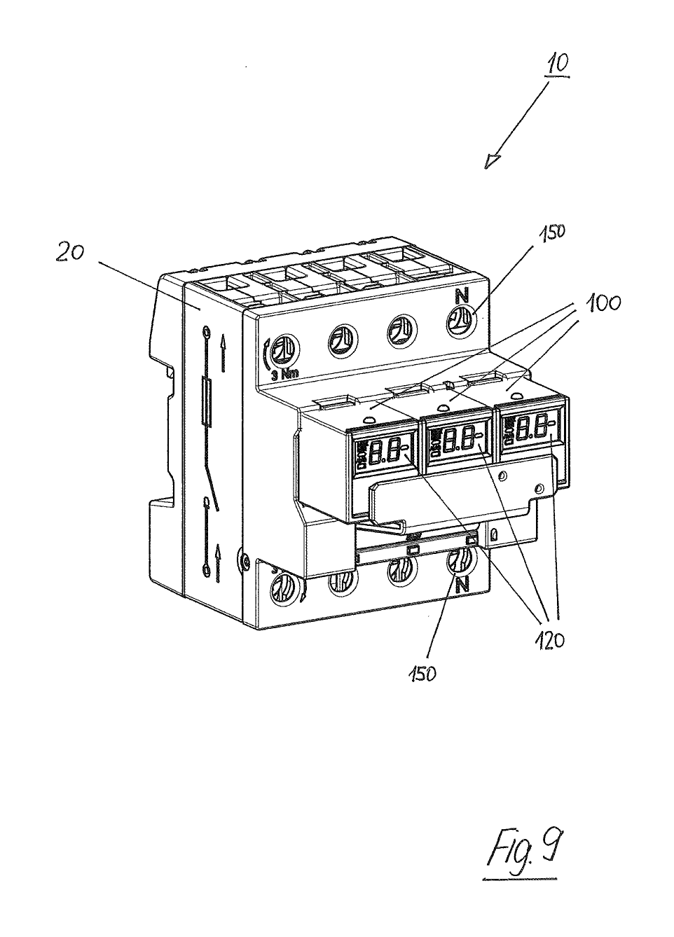

FIG. 9 shows a further form of embodiment of an inventive module; and

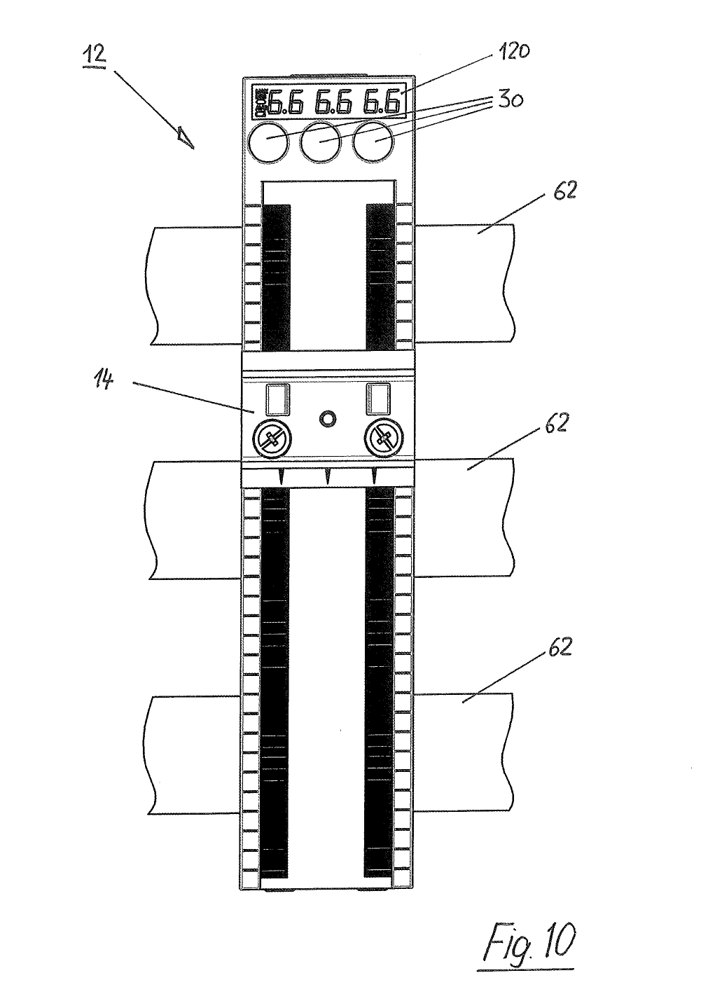

FIG. 10 shows a further form of embodiment of an inventive module; and

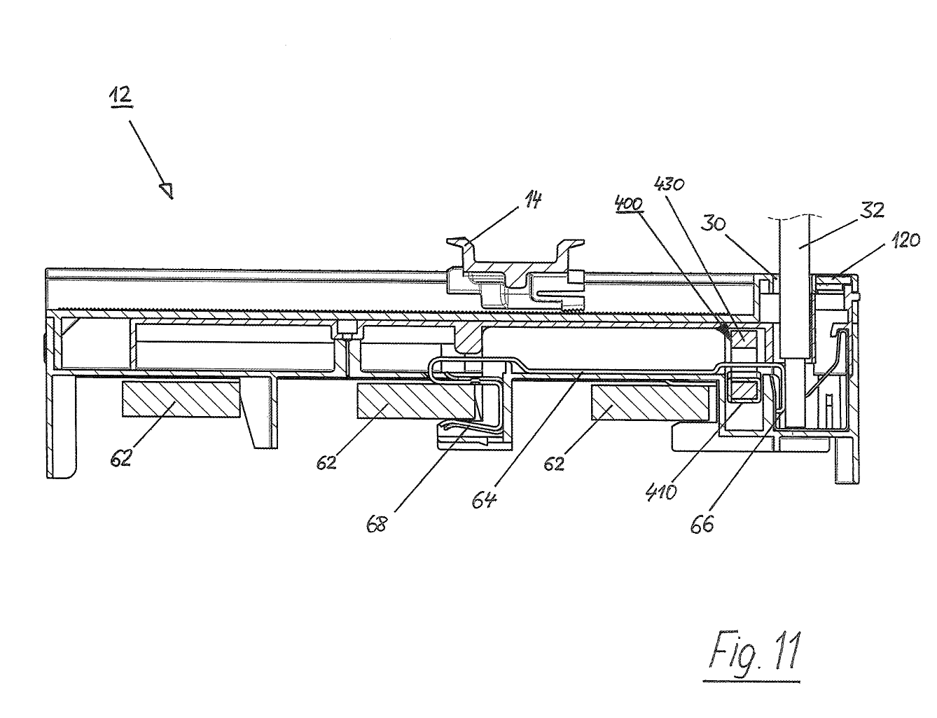

FIG. 11 shows a schematic cross-section through the form of embodiment shown in FIG. 10.

FIG. 1 shows a perspective view of a first form of embodiment of an inventive module, wherein this form of embodiment takes the form of a fused switch arrangement 10; this is of a 3-pole design, and therefore comprises three fused switch units, in each of which a fuse holder 100 is inserted. The said fused switch arrangement 10 takes the form of a fused switch arrangement 10 for a busbar system. The fused switch units are accommodated in a housing 20 of the fused switch arrangement 10.

In this form of embodiment the fused switch arrangement comprises a common housing 20, wherein the individual fused switch units are separated by dividing walls. However, this can be implemented in another manner, for example in terms of individual housings for each fused switch unit that are separated from one another, which, for example, are just connected with one another.

The fused switch arrangement 10 comprises attachment devices 60 for purposes of attaching the fused switch unit onto busbars (not shown) of a busbar system.

In the form of embodiment shown in FIG. 1 a total of three fuse holders 100 are inserted into the fused switch arrangement 10. The fused switch unit can be switched on or off by means of a switch 40.

Each of the fuse holders 100 comprises a display device 120 for purposes of displaying electrical operating values, in particular for purposes of displaying the voltage, current, and/or power of the respective phase of the fused switch unit 10.

FIG. 2 shows a perspective view of a form of embodiment of an inventive fuse holder 100 with a display 120, as can also be used in the fused switch unit 10 shown in FIG. 1. A fuse insert 200 is inserted into the fuse holder 100.

FIG. 3 shows a scrap view of another form of embodiment of an inventive module, wherein this module also takes the form of a fused switch arrangement 10. In contrast to the form of embodiment shown in FIG. 1 a display device 120 is provided in the housing 20 of the fused switch arrangement 10. In this form of embodiment the housing 20 comprises a total of three display devices 120, one display device for each phase; however, it is also possible for a common display device to be provided for all phases.

FIG. 4 shows a schematic diagram, which represents important elements of a form of embodiment of an inventive module: A fuse insert 200 is operated in a module, the line L symbolises a conductor, i.e. a current path. As can be seen from FIG. 4, a coil device 400 is provided, which comprises a coil former 430, a first coil winding 410, and also a second coil winding 420.

As a result of the alternating current that is conducted through the conductor L, and thus through the fuse insert 200, a current is induced in the conductors of the first coil winding 410 and the second coil winding 420.

The first coil winding 410 is, directly or indirectly, connected with a set of measurement electronics 300, and by means of the induced current supplies energy to the latter and the display device 120 that is connected with it.

The second coil winding 420 is likewise, directly or indirectly, connected with the set of measurement electronics 300, and serves to determine the electrical operating values.

The device comprises a display device 120, which is likewise connected with the measuring device and can display the electrical operating values determined.

The elements represented in FIG. 4 can be provided either in a housing of a module, or in a fuse holder.

FIG. 5 shows a cross-section through a form of embodiment of an inventive fuse holder 100, into which a fuse insert 200 is inserted. The fuse insert 200 makes contact with a lower contact 530 of the fuse holder 100, which in turn is connected via a shunt 540 with an upper contact 520 of the fuse holder 100.

As can easily be seen in FIG. 5, the fuse holder 100 comprises a coil device 400 with a coil former 430 and a first coil winding 410 (just represented schematically) and a second coil winding (not shown), wherein with regard to the connection of these elements reference is made to FIG. 4 and the related explanation.

The fuse holder shown in FIG. 5 furthermore comprises a display device 120, which comprises a display 122 and a protective disk 124 arranged in front of it.

Furthermore the form of embodiment of the fuse holder shown in FIG. 5 comprises a battery 660 for purposes of providing an additional supply to the measuring device, and a button 620, with which the measuring device can be switched on and off. Furthermore in the form of embodiment shown in FIG. 5 the button 620 comprises further functional features, since the measuring device can optionally be switched by means of the button 620 such that it measures either the current or the power. Optionally it is also possible for a minimum value, a maximum value, or an average value of the measurements to be displayed by means of the button. Both the battery 660 and also the button 620 are just optional elements.

FIG. 6 shows a scrap cross-section through a further form of embodiment of an inventive module, wherein the latter again takes the form of a fused switch arrangement 10 with fuse holders 100, of which only one fuse holder is shown, into which a fuse insert 200 has been inserted. Both the measuring device and the display device are arranged in the housing 20 of the fused switch arrangement 10.

In an analogous manner to the form of embodiment shown in FIG. 5 this fused switch arrangement 10 also comprises a display device 120 with a display 122 and a protective disk 124, as well as an optional battery 660 and a button 620; however, these elements are arranged in the housing 20 of the fused switch arrangement 10 and not in the fuse holder 100.

FIG. 7 shows a cross-section through a further form of embodiment of an inventive fuse holder 100, which essentially corresponds to the form of embodiment shown in FIG. 5, so that for purposes of avoiding repetition reference is made to FIG. 5 and the related description.

In contrast to the form of embodiment shown in FIG. 5 the form of embodiment of the inventive fuse holder 100 shown in FIG. 7 does not feature a battery or any other additional energy supply.

FIG. 8 shows a schematic diagram, which represents important elements of a further form of embodiment of an inventive module, or an inventive fuse holder.

In an analogous manner to the form of embodiment shown in FIG. 4 the form of embodiment shown in FIG. 8 comprises a coil device 400 with a coil core 430 and a first coil winding 410 for purposes of supplying energy to the set of measurement electronics 300 and/or the display device 120. However, this form of embodiment does not feature a second coil winding for purposes of aiding the measurement of the electrical operating values. The said operating values are measured via a shunt 540 in connection with the set of measurement electronics 300. In both the form of embodiment shown in FIG. 4 and that shown in FIG. 8 the shunt 540 is connected to a microprocessor, wherein the microprocessor is part of the set of measurement electronics 300. Optionally it is possible to provide an amplifier, which is preferably also part of the set of measurement electronics 300.

This form of embodiment additionally comprises a neutral conductor, which is connected with the set of measurement electronics 300, so that additional operating values, such as, for example, the power, can also be measured.

In the form of embodiment shown in FIG. 8 optional elements are provided, namely a button 620, a battery 660, and a solar cell 680, wherein it must be pointed out that these elements can be provided either collectively or individually, but do not have to be provided.

FIG. 9 shows a further form of embodiment of an inventive module, wherein in this form of embodiment the module does not take the form of a fused switch arrangement for busbar systems, but rather takes the form of a built-in device.

The functional elements, in particular the housing and the fuse holder, correspond essentially to the fused switch arrangement as has been described above. The same or similar elements are therefore provided with identical reference symbols, and for purposes of avoiding repetition reference is made to the above-described form of embodiment with regard to its features and advantages.

The form of embodiment of the fused switch unit 10 shown in FIG. 9 comprises a housing 20. The fused switch arrangement 10 takes the form of a 3-pole fused switch arrangement, into which a total of three fuse holders 100 can be inserted. Each of the fuse holders 100 comprises a display 120 for purposes of displaying the operating values determined

The form of embodiment of the fused switch arrangement shown in FIG. 9 also comprises terminal connections 150 for a neutral conductor; with regard to the advantages of such a terminal connection and neutral conductor reference is made to the above description.

FIG. 10 shows a further form of embodiment of an inventive module, wherein this module takes the form of a busbar adapter 12, which can be attached to busbars. In the form of embodiment shown here this takes the form of a 3-pole system with three busbars 62.

The busbar adapter 12 comprises a carrier rail 14, onto which can be positioned related built-in devices, in particular rail-mounted devices.

The busbar adapter 12 shown in FIG. 10 comprises a display device 120 for purposes of displaying the operating values, wherein in this form of embodiment operating values for both the total system and also for each individual phase can be displayed, as shown in FIG. 10.

The busbar adapter 12 comprises a total of three openings 30 for connecting conductors of the system.

FIG. 11 shows schematically a cross-section through the busbar adapter 12 shown in FIG. 10, wherein in this cross-sectional view it is particularly easy to see the attachment devices 60 for purposes of attaching the busbar adapter 12 to the busbars 62.

The cross-section shown in FIG. 11 shows a plane of the busbar adapter 12, in which runs a tapping contact 68 for the central busbar 62.

The tapping contact 68 is designed integrally with a tapping conductor 64, which leads to a connecting point 66, which is connected with a connecting conductor 32, which is introduced into the opening 30 of the busbar adapter 12.

FIG. 11 likewise shows schematically a coil device 400 with a coil core 430 and a first coil winding 410, which, as described in the context of the other forms of embodiment, delivers energy for the measuring device by means of induction. Optionally a second coil winding 420, or another device, can also be provided, such as, for example, a shunt by means of which the electrical operating values of the system are determined, in this case of the phase that is connected with the central busbar 62.

With regard to the functionality and the advantages of such a form of embodiment reference is made to the above descriptions.

The features of the invention disclosed in the above description, the claims, and the figures can be of importance, both individually, and also in any combinations for realisation.

1. A module for a fused switch arrangement (10), wherein the module comprises a measuring device for purposes of determining electrical operating values, and wherein the measuring device has a set of measurement electronics (300) and at least one display device (120) for purposes of displaying at least one of the electrical operating values determined by the measuring device, and wherein the module comprises at least one coil device (400), which is designed such that by means of induction it can provide energy for at least one of the set of measurement electronics (300) and the at least one display device (120).

2. The module in accordance with claim 1, wherein the at least one coil device (400) has a coil former (430) and at least one coil winding (410, 420).

3. The module in accordance with claim 1, wherein the coil device (400) comprises at least two coil windings (410, 420), wherein at least one first coil winding (410) is designed such that it provides energy for at least one of the set of measurement electronics (300) and the at least one display device (120), wherein at least one second coil winding (420) is connected with the measuring device such that by means of the at least one second coil winding (420) and the set of measurement electronics (300) electrical operating values can be determined.

4. The module in accordance with claim 1 wherein the measuring device is designed such that electrical operating values for each of the phases of at least one of the module and of a fused switch arrangement (10) can be separately determined.

5. The module in accordance with claim 1 wherein the measuring device comprises a set of measurement electronics (300) for each phase.

6. The module in accordance with claim 1 wherein the measuring device comprises a display device (120) for each phase.

7. The module in accordance with claim 1 further comprising at least one coil device (400) for each phase.

8. The module in accordance with claim 1 further comprising a housing, wherein at least one of the set of measurement electronics (300), the at least one display device (120), and the at least one coil device (400) is arranged in at least one of the following manners: (1) in the housing; and (2) on the housing.

9. The module in accordance with claim 1 further comprising at least one fuse holder (100).

10. The module in accordance with claim 9, wherein the at least one fuse holder (100) comprises a set of measurement electronics (300), at least one display device (120), and at least one coil device (400).

11. The module in accordance with claim 1 further comprising at least one of an accumulator, a battery (660), and a solar cell (680), for supplying energy to the measuring device.

12. The module in accordance with claim 1 further comprising one of a neutral conductor connected directly to the measuring device (300); and a neutral conductor connected indirectly to the measuring device (300).

13. The module in accordance with claim 1 wherein the module is one of: (1) a fused switch arrangement for busbar systems; and (2) a built-in device, and the module comprises at least one fused switch unit for accommodating in each case a fuse holder (100), for accommodating a fuse insert.

14. A fuse holder (100) for at least one of a module of a fused switch arrangement, and a fused switch arrangement (10), the fuse holder for accommodating a fuse insert (200), the fuse holder comprising a measuring device for determining electrical operating values, wherein the measuring device has a set of measurement electronics (300) and at least one display device (120) for displaying at least one of the electrical operating values determined by the measuring device, and wherein the fuse holder (100) comprises at least one coil device (400) for providing energy for at least one of the set of measurement electronics (300) and the at least one display device (120) by means of induction.

15. The fuse holder in accordance with claim 14, wherein the at least one coil device (400) has a coil former (430) and at least one coil winding.

16. The fuse holder in accordance with claim 14, wherein the at least one coil device (400) comprises
at least one first coil winding (410) that provides energy for at least one of the set of measurement electronics (300) and the at least one display device (120), and
at least one second coil winding (420) is connected with the measuring device such that by means of the at least one second coil winding (420) and the set of measurement electronics (300) electrical operating values can be determined.

17. The fuse holder in accordance with claim 14, further comprising at least one of an accumulator, battery (660), and a solar cell (680), for supplying energy to the measuring device (300).
